(19) United States
(12) Patent Application Publication
(10) Pub. No.: US 2026/0347075 A1
(43) Pub. Date: Nov. 5, 2026

(54) PACKAGING AND PACKAGING PRODUCT

(71) Applicant: TOPPAN Holdings Inc., Tokyo (JP)

(72) Inventors: Rika ISHII, Taito-ku, Tokyo (JP); Junichi KAMINAGA, Taito-ku, Tokyo (JP); Yoshiki KOSHIYAMA, Taito-ku, Tokyo (JP); Yumiko KOJIMA, Taito-ku, Tokyo (JP); Hiroyuki WAKABAYASHI, Taito-ku, Tokyo (JP)

(73) Assignee: TOPPAN Holdings Inc., Tokyo (JP)

(21) Appl. No.: 19/101,487

(22) PCT Filed: Aug. 23, 2023
(86) PCT No.: PCT/JP2023/030330

§ 371 Date: Feb. 5, 2025

(30) Foreign Application Priority Data
Aug. 29, 2022 (JP) 2022-135985

(51) Int. Cl. B65D 75/00; B65D 75/26; C23C 14/20; C23C 14/24; D21H 11/04; D21H 19/08; D21H 19/12; D21H 19/20; D21H 19/82; D21H 27/10

(52) U.S. Cl. CPC B65D 75/008; B65D 75/26; C23C 14/20; C23C 14/24; D21H 11/04; D21H 19/08; D21H 19/12; D21H 19/20; D21H 19/82; D21H 27/10

(57) ABSTRACT

The packaging includes: a pair of body members, and a bottom member bent and inserted between the body members; a first seal portion formed by heat-sealing peripheral portions of the body portions of the body members; and a second seal portion formed by heat-sealing peripheral portions of the bottom portions of the body members and a peripheral portion of the bottom member. The body member and the bottom member include a paper substrate, an anchor coat layer, a vapor deposition layer, and a heat seal layer. The thickness of the heat seal layer of the body member is 2 to 5 μm, the thickness of the heat seal layer of the bottom member/the thickness of the heat seal layer of the body member is 5 or more, and the mass ratio of the paper substrate to the total mass of the packaging is 70 mass % or more.

### TECHNICAL FIELD

The present disclosure relates to a packaging and a packaging product.

### BACKGROUND ART

Conventionally, as a packaging bag, a packaging having a standing pouch shape that is obtained by using a pair of body members and a bottom member, and heat-sealing them to form a bag.

As such a packaging, for example, there is known a self-supporting packaging bag, and the packaging bag has a standing pouch shape, and formed by: overlapping two laminates mainly made of paper and constituting the body portion such that two thermoplastic resin surfaces capable of heat-sealing face each other; and folding the bottom portion made of a bottom film into a V-shape, followed by heat-sealing the peripheral edge, wherein the laminate has a body portion and an outer bottom plate, the inner surface of the body portion and the seal portion of the bottom film are sealed to form an inner bottom portion, and the outer bottom plates of the laminates each are bent inward and bonded between the inner surface and the outer surface to form an outer bottom portion (For example, see Patent Literature 1 below).

### CITATION LIST

### Patent Literature

Patent Literature 1: Japanese Unexamined Patent Publication No. 2011-73714

### SUMMARY OF INVENTION

### Technical Problem

Meanwhile, in recent years, the momentum of deplasticization has been growing due to an increase in environmental awareness caused by marine plastic waste problems and the like. Therefore, a packaging having a standing pouch shape is also required to include a paper substrate in a higher mass ratio in its body members and bottom member.

However, the packaging bag described in Patent Literature 1 has the following problems.

That is, the packaging bag described in Patent Literature 1 has room for improvement in gas barrier property and durability when the mass ratio of a paper substrate is increased. In addition, the packaging bag described in Patent Literature 1 has room for improvement also in the sealing property of a packaging product obtained by sealing a content when the mass ratio of a paper substrate is increased.

The present disclosure has been made in view of the above problems, and an object of the present disclosure is to provide a packaging and a packaging product that can improve gas barrier properties and durability while increasing the mass ratio of a paper substrate, and can also improve the sealing property of a packaging product obtained by sealing a content.

### Solution to Problem

In order to solve the above problems, one aspect of the present disclosure provides: a packaging having a standing pouch shape, the packaging including: a pair of body members having a body portion and a bottom portion, and a bottom member bent and inserted between the pair of body members; a first seal portion formed by heat-sealing peripheral portions of the body portions of the pair of body members; and a second seal portion formed by heat-sealing peripheral portions of the bottom portions of the pair of body members and a peripheral portion of the bottom member, wherein the body member and the bottom member include a paper substrate, an anchor coat layer, a vapor deposition layer containing a metal or a metal oxide, and a heat seal layer in this order, the first seal portion is formed by heat-sealing the heat seal layers of the pair of body members,
the second seal portion is formed by heat-sealing the heat seal layer of the body member and the heat seal layer of the bottom member, a thickness of the heat seal layer of the body member is in a range of 2 to 5 μm, a ratio of a thickness of the heat seal layer of the bottom member to a thickness of the heat seal layer of the body member is 5 or more, and a mass ratio of the paper substrate to a total mass of the packaging is 70 mass % or more.

The packaging can improve gas barrier properties and durability while increasing the mass ratio of a paper substrate, and can also improve the sealing property of a packaging product obtained by sealing a content.

The reason why the above effects can be obtained is presumed as follows.

That is, when the thickness of the heat seal layer of the pair of body members is reduced to 2 to 5 μm, and the ratio of the thickness of the heat seal layer of the bottom member to the thickness of the heat seal layer of the body member is 5 or more, the proportion of the surface area of the pair of body members in the packaging is large, so that the mass ratio of the paper substrate in the total mass of the packaging can be increased. In addition, when the ratio of the thickness of the heat seal layer of the bottom member to the thickness of the heat seal layer of the body member is 5 or more, the packaging can improve the gas barrier property of the bottom member even when the bottom member is bent, compared to the case where the ratio is less than 5. In addition, when the packaging includes: a first seal portion formed by heat-sealing peripheral portions of the body portions of the pair of body members; and a second seal portion formed by heat-sealing peripheral portions of the bottom portions of the pair of body members and a peripheral portion of the bottom member, the heat seal layer of the bottom member having a thickness sufficiently larger than that of the body member is melted, and at the intersection between the first seal portion and the second seal portion of the packaging, where a gap is easily formed due to the step, the melted heat seal layer sufficiently fills the space to suppress the generation of a gap. Therefore, in the packaging product obtained by sealing a content in the packaging, leakage of the content from the gap is suppressed, and the sealing property of the packaging product can be improved. Furthermore, a gap is less likely to occur at the intersection between the first seal portion and the second seal portion of the packaging. Therefore, even if the packaging product obtained by sealing a content in the packaging is dropped and impacted, peeling of the first seal portion and peeling of the second seal portion due to the gap are easily suppressed. Therefore, the packaging of the present disclosure can also improve durability.

In the packaging, preferably, no gap is formed at an intersection between the first seal portion and the second seal portion.

In this case, no gap is formed at an intersection between the first seal portion and the second seal portion. Therefore, in the packaging product obtained by sealing a content in the packaging, leakage of the content from the gap is further suppressed, and the sealing property of the packaging product can be further improved. Furthermore, even if the packaging product obtained by sealing a content in the packaging is dropped and impacted, peeling of the first seal portion and peeling of the second seal portion due to the gap are further easily suppressed in the packaging product. Therefore, the packaging of the present disclosure can also further improve durability.

In the packaging, optionally, the heat seal layer of the body member is formed of a coating film obtained by coating and drying an aqueous dispersion in which a polyolefin having at least one selected from the group consisting of a carboxyl group and a salt of a carboxyl group (hereinafter, sometimes referred to as “carboxyl group/carboxyl group salt”) is dispersed in water as a resin component, and the heat seal layer of the bottom member is a polyolefin film.

In this case, the heat seal layer is a coating film obtained by coating and drying an aqueous dispersion in which a polyolefin having carboxyl group/carboxyl group salt is dispersed in water as a resin component. Therefore, easy openability of the packaging can be enhanced. In addition, the heat seal layer can be formed thin, and the mass ratio of the paper substrate to the total mass of the packaging can be easily increased. In addition, the heat seal layer of the bottom member is a polyolefin film. Therefore, the strength of the bottom member is more improved compared to the case where the heat seal layer is the above-described coating film, and the packaging can improve the gas barrier property even when the bottom member is bent in the packaging.

In the packaging, when the heat seal layer is a polyolefin film, the bottom member may further include an adhesive layer between the vapor deposition layer and the heat seal layer.

In this case, adhesion between the vapor deposition layer and the heat seal layer can be improved, and peeling between the vapor deposition layer and the heat seal layer can be suppressed.

In the packaging, the bottom member may further include an overcoat layer between the vapor deposition layer and the adhesive layer.

In the packaging, the overcoat layer may have a polyolefin having at least one selected from the group consisting of a carboxyl group and a salt of a carboxyl group.

In the packaging, the ratio of the thickness of the paper substrate of the bottom member to the total thickness of the heat seal layer of the body member and the heat seal layer of the bottom member may be greater than 0.5.

In this case, the mass ratio of the paper substrate in the total mass of the packaging can be easily increased.

In the packaging, the ratio of the thickness of the paper substrate of the bottom member to the total thickness of the heat seal layer of the body member and the heat seal layer of the bottom member may be 5.0 or less.

In the packaging, in the body member and the bottom member, the anchor coat layer may have a polyolefin having at least one selected from the group consisting of a carboxyl group and a salt of a carboxyl group.

In this case, the anchor coat layer is excellent in flexibility. Therefore, cracking of the vapor deposition layer can be suppressed even when the body member and the bottom member are bent, and adhesion between the anchor coat layer and the vapor deposition layer can be further improved.

In the packaging, in the body member and the bottom member, the anchor coat layer may contain a polyvinyl alcohol.

In this case, the anchor coat layer is excellent in flexibility. Therefore, cracking of the vapor deposition layer can be suppressed even when the body member and the bottom member are bent, and adhesion between the anchor coat layer and the vapor deposition layer can be further improved.

In the packaging, in the body member and the bottom member, the anchor coat layer may contain a polyurethane-based resin.

In this case, the gas barrier property of the packaging can be further improved.

In the packaging, the ratio of the thickness of the heat seal layer of the bottom member to the thickness of the heat seal layer of the body member may be 100 or less.

In the packaging, the paper substrate may be an uncoated paper having no clay coat layer.

Another aspect of the present disclosure provides: a packaging product obtained by sealing a content in the packaging.

The packaging can improve gas barrier properties and durability while increasing the mass ratio of a paper substrate in the total mass of the packaging, and can also improve the sealing property.

### Advantageous Effects of Invention

According to the present disclosure, it is possible to provide a packaging and a packaging product that can improve gas barrier properties and durability while increasing the mass ratio of a paper substrate, and can also improve the sealing property of a packaging product obtained by sealing a content.

### BRIEF DESCRIPTION OF DRAWINGS

FIG. 1 is a front view illustrating an embodiment of a packaging of the present disclosure.

FIG. 2 is a cross-sectional view along the line II-II in FIG. 1.

FIG. 3 is a cross-sectional view illustrating the body member in FIG. 1.

FIG. 4 is a cross-sectional view illustrating the bottom member in FIG. 1.

FIG. 5 is a cross-sectional view illustrating a modification of the body member in FIG. 1.

FIG. 6 is a cross-sectional view illustrating a modification of the bottom member in FIG. 1.

FIG. 7 is a front view illustrating an embodiment of a packaging product of the present disclosure.

### DESCRIPTION OF EMBODIMENTS

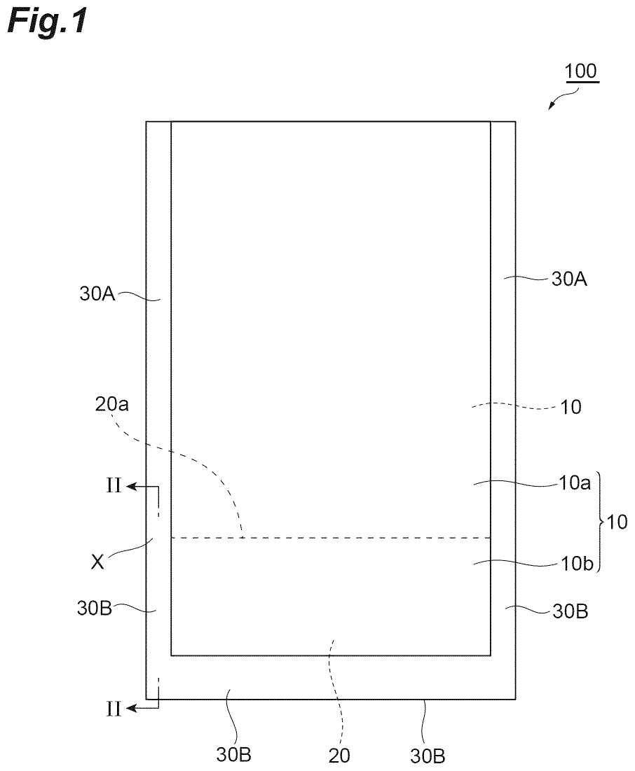

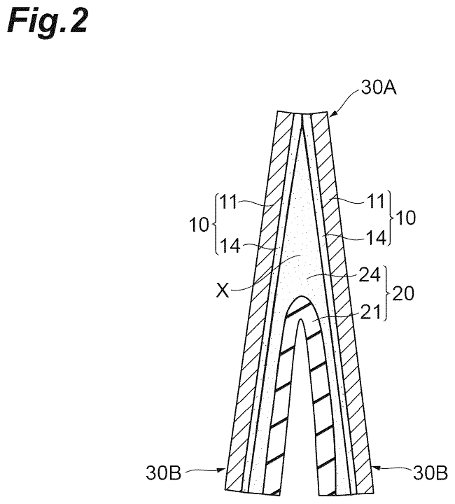

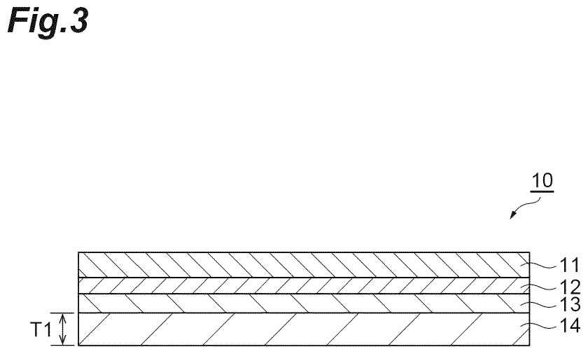

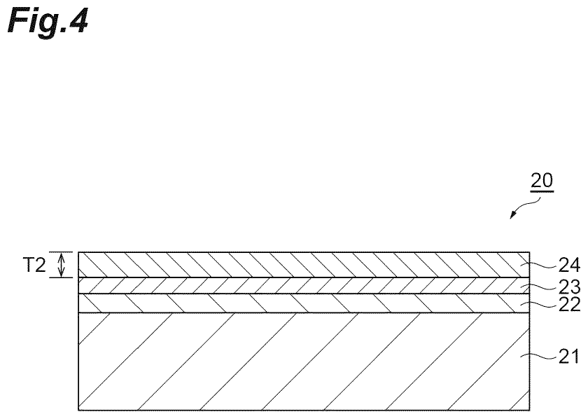

Hereinafter, an embodiment of the packaging of the present disclosure will be described in detail with reference to FIGS. 1 to 4. FIG. 1 is a front view illustrating an embodiment of a packaging of the present disclosure, FIG. 2 is a cross-sectional view along the line II-II in FIG. 1, FIG. 3 is a cross-sectional view illustrating the body member in FIG. 1, and FIG. 4 is a cross-sectional view illustrating the bottom member in FIG. 1.

A packaging 100 illustrated in FIGS. 1 and 2 includes: a pair of body members 10 having a body portion 10a and a bottom portion 10b, and a bottom member 20 bent and inserted between the pair of body members 10; a first seal portion 30A formed by heat-sealing peripheral portions of the body portions 10a of the pair of body members 10; and a second seal portion 30B formed by heat-sealing peripheral portions of the bottom portions 10b of the pair of body members 10 and a peripheral portion of the bottom member 20.

As illustrated in FIG. 3, the pair of body members 10 include a paper substrate 11, an anchor coat layer 12, a vapor deposition layer 13 containing a metal or a metal oxide, and a heat seal layer 14 in this order, and the thickness T1 of the heat seal layer 14 of the body member 10 is in a range of 2 to 5 μm.

As illustrated in FIG. 4, the bottom member 20 includes a paper substrate 21, an anchor coat layer 12, a vapor deposition layer 23 containing a metal or a metal oxide, and a heat seal layer 24 in this order, and the ratio R of the thickness T2 of the heat seal layer 24 of the bottom member 20 to the thickness T1 of the heat seal layer 14 of the body member 10 (T2/T1) is 5 or more.

The first seal portion 30A is formed by heat-sealing the heat seal layers 14 of the pair of body members 10, and the second seal portion 30B is formed by heat-sealing the heat seal layer 14 of the body member 10 and the heat seal layer 24 of the bottom member 20.

The mass ratio of the paper substrates 11 and 21 to the total mass of the packaging 100 is 70 mass % or more.

The packaging 100 can improve gas barrier properties and durability while increasing the mass ratio of the paper substrates 11 and 21, and can also improve the sealing property of a packaging product obtained by sealing a content.

Hereinafter, the body member 10, the bottom member 20, and the mass ratio of the paper substrate to the total mass of the packaging 100 will be described in detail.

### <Body Member>

As described above, the body member 10 includes a paper substrate 11, an anchor coat layer 12, a vapor deposition layer 13, and a heat seal layer 14 in this order.

### (Paper Substrate)

The paper substrate 11 is not particularly limited as long as it is a substrate having paper. Here, the paper refers to a material containing plant-derived pulp as a main component. The main component refers to a component containing 50 mass % or more of plant-derived pulp in the material. Since the body member 10 includes the paper substrate 1, it is possible to contribute to reduction in the amount of plastic material used.

Specific examples of the paper substrate 11 include high-quality paper, special high-quality paper, coated paper, art paper, cast coated paper, imitation paper and kraft paper, and glassine paper.

The basis weight of the paper substrate 11 is not particularly limited, and may be, for example, 20 g/m² or more, or may be 30 g/m² or more, but is preferably 30 g/m² or more from the viewpoint of self-standing of the packaging 100. The basis weight of the paper substrate 11 may be 500 g/m² or less, and may be 100 g/m² or less.

The paper substrate 11 may further include a coating layer at least on the anchor coat layer 12 side of the paper. When the paper substrate 11 further includes the coating layer, it is possible to prevent the anchor coat layer 12 from soaking into the paper, improve gas barrier properties, serve as a filling agent for filling irregularities of the paper, and form the anchor coat layer 12 uniformly without defects. The coating layer may further contain a binder resin and, if necessary, a filler. Examples of the binder resin include various copolymers such as a styrene-butadiene copolymer, a styrene-acrylic copolymer, and an ethylene-vinyl acetate copolymer, a polyvinyl alcohol-based resin, and a cellulose-based resin. Examples of the filler include kaolin, calcium carbonate, talc, and mica.

The thickness of the coating layer is not particularly limited, but may be, for example, 1 μm or more, or may be 3 μm or more. The thickness of the coating layer may be 10 μm or less, or may be 8 μm or less.

The paper substrate 11 may be made only of paper. That is, the paper substrate 11 may be an uncoated paper having no coating layer.

### (Anchor Coat Layer)

The anchor coat layer 12 is provided on the surface of the paper substrate 11, and is provided for improving adhesion between the paper substrate 1I and the vapor deposition layer 13 and improving the gas barrier properties of the body member 10.

The anchor coat layer 12 is not particularly limited, and may contain at least one of a polyolefin having carboxyl group/carboxyl group salt, a polyvinyl alcohol, and a polyurethane-based resin. When the anchor coat layer 12 contains at least one of a polyolefin having carboxyl group/carboxyl group salt and a polyvinyl alcohol, the anchor coat layer 12 is excellent in flexibility, can suppress cracking of the vapor deposition layer 13 even when the body member 10 is bent, and can improve adhesion between the paper substrate 11 and the vapor deposition layer 13. When the anchor coat layer 12 contains a polyurethane-based resin, the gas barrier property of the packaging 100 can be further improved.

In particular, when the anchor coat layer 12 contains the polyolefin described above, the anchor coat layer 12 can be formed as a dense film due to the crystallinity of the polyolefin. In addition, the polyolefin, having few polar groups, can improve the water vapor barrier property of the body member 10.

When the anchor coat layer 12 contains the polyvinyl alcohol described above, the oxygen barrier property of the body member 10 can be further improved.

When the anchor coat layer 12 contains a polyolefin having carboxyl group/carboxyl group salt, the polyolefin to be used includes a copolymer of an olefin such as ethylene or propylene with an unsaturated compound such as acrylic acid, methacrylic acid, or maleic anhydride. Specific examples thereof include a copolymer of ethylene and acrylic acid, a copolymer of ethylene and methacrylic acid, a copolymer of propylene and acrylic acid, a copolymer of propylene and methacrylic acid, and a copolymer of ethylene and maleic anhydride.

Examples of the polyvinyl alcohol include fully saponified polyvinyl alcohol, partially saponified polyvinyl alcohol, modified polyvinyl alcohol, and an ethylene-vinyl alcohol copolymer resin. The polymerization degree of the polyvinyl alcohol is preferably 300 or more and 1500 or less. When the polymerization degree is 300 or more, the barrier property and bending resistance of the body member 10 are improved, and when the polymerization degree is 1500 or less, the viscosity of the polyvinyl alcohol coating liquid is reduced, and the coatability is improved.

The polyurethane-based resin is not particularly limited as long as it is a resin having a urethane bond, but preferably contains at least one of a structural unit derived from meta-xylylene diisocyanate and a structural unit derived from hydrogenated meta-xylylene diisocyanate from the viewpoint of barrier properties. When the polyurethane-based resin contains such a structural unit, a high cohesive force is exhibited by a hydrogen bond and a stacking effect between xylylene groups, so that the gas barrier property tends to be further improved. The coating liquid used for forming the anchor coat layer containing the polyurethane-based resin is preferably a coating liquid in which the resin is dispersed in water, such as a dispersion or an emulsion, from the viewpoint of coatability. Examples of such a coating liquid include TAKELAC WPB, which is manufactured by Mitsui Chemicals, Inc.

The anchor coat layer 12 may contain other components in addition to the polyolefin, polyvinyl alcohol, or polyurethane-based resin. Examples of other components include a polyolefin other than the above-described polyolefin, a silane coupling agent, an organic titanate, a polyacrylic, a polyester, a polyurethane, a polycarbonate, a polyurea, a polyamide, a polyimide, a melamine, and a phenol.

In the anchor coat layer 12, the content of the polyolefin or polyvinyl alcohol may be, for example, 50 mass % or more, 70 mass % or more, 90 mass % or more, or 100 mass %.

The thickness of the anchor coat layer 12 may be, for example, 1 μm or more, 2 μm or more, or may be 20 μm or less. The thickness of the anchor coat layer 12 may be 10 μm or less, or may be 5 μm or less. When the thickness of the anchor coat layer 12 is 1 μm or more, the irregularities of the paper substrate 11 described above can be efficiently filled, and the vapor deposition layer 13 can be uniformly deposited. When the thickness of the anchor coat layer 12 is 20 μm or less, the vapor deposition layer 13 can be uniformly deposited while suppressing the cost.

As the method for forming the anchor coat layer 12, a coating liquid containing at least the above-mentioned polyolefin or polyvinyl alcohol and a solvent is applied onto the paper substrate 11, followed by drying, to obtain the anchor coat layer 12. The average particle size of the polyolefin or polyvinyl alcohol in the coating liquid is preferably as small as possible from the viewpoint of smoothing the coating surface after drying, uniformly depositing the vapor deposition layer 13, and improving the barrier property. Specifically, the average particle size of the polyolefin or polyvinyl alcohol in the coating liquid may be 1 μm or less, 0.7 μm or less, or 0.5 μm or less. The lower limit of the average particle size of the polyolefin or polyvinyl alcohol is not particularly limited, but may be, for example, 1 nm.

Examples of the solvent contained in the coating liquid include water, methyl alcohol, ethyl alcohol, isopropyl alcohol, n-propyl alcohol, n-butyl alcohol, n-pentyl alcohol, dimethyl sulfoxide, dimethylformamide, dimethylacetamide, toluene, hexane, heptane, cyclohexane, acetone, methyl ethyl ketone, diethyl ether, dioxane, tetrahydrofuran, ethyl acetate, and butyl acetate. These solvents may be used singly or in combination of two or more kinds thereof. Among them, methyl alcohol, ethyl alcohol, isopropyl alcohol, toluene, ethyl acetate, methyl ethyl ketone, and water are preferable from the viewpoint of characteristics. In addition, from the viewpoint of the environment, methyl alcohol, ethyl alcohol, isopropyl alcohol, and water are preferable.

### (Vapor Deposition Layer)

The vapor deposition layer 13 contains a metal or a metal oxide. The vapor deposition layer 13 is obtained by vapor-depositing a metal or a metal oxide. Examples of the metal include aluminum (AL). Examples of the metal oxide include an inorganic oxide such as aluminum oxide (AlOₓ) and silicon oxide (SiOₓ).

The thickness of the vapor deposition layer 13 may be appropriately set depending on the use of the packaging 100, and is preferably 30 nm or more, and more preferably 50 nm or more. When the thickness of the vapor deposition layer 13 is 30 nm or more, continuity of the vapor deposition layer 13 can be improved. The thickness of the vapor deposition layer 13 is preferably 100 nm or less, more preferably 80 nm or less. When the thickness of the vapor deposition layer 13 is 100 nm or less, the vapor deposition layer 13 can be sufficiently inhibited from occurrence of curl and cracks, and sufficient gas barrier properties and flexibility can be easily achieved.

The vapor deposition layer 13 is preferably deposited by a vacuum deposition means from the viewpoint of oxygen gas barrier properties and film uniformity. As the vacuum deposition means, there are known methods such as a vacuum vapor deposition method, a sputtering method, and a chemical vapor deposition method (CVD method), but the vacuum vapor deposition method is preferable because the deposition rate is high and productivity is high. Among the vacuum vapor deposition methods, particularly, the deposition means by electron beam heating is effective because the deposition rate can be easily controlled by an irradiation area, an electron beam current, or the like, and the temperature of the vapor deposition material can be raised and lowered in a short time.

### (Heat Seal Layer)

The heat seal layer 14 has heat-sealing property. The heat seal layer 14 and the anchor coat layer 12 sandwich the vapor deposition layer 13. Thereby, the vapor deposition layer 13 can be protected.

The material of the heat seal layer 14 is not particularly limited. Examples thereof include a coating film obtained by coating and drying an aqueous dispersion in which a polyolefin having carboxyl group/carboxyl group salt is dispersed in water as a resin component (heat seal varnish).

In this case, the heat seal layer 14 is a coating film obtained by coating and drying an aqueous dispersion in which a polyolefin having carboxyl group/carboxyl group salt is dispersed in water as a resin component. Therefore, easy openability of the packaging 100 can be enhanced. In addition, the heat seal layer 14 can be formed thin, and the mass ratio of the paper substrate to the total mass of the packaging 100 can be easily increased.

The polyolefin having carboxyl group/carboxyl group salt includes a polyolefin that is a copolymer of an olefin such as ethylene or propylene with a salt of an unsaturated carboxylic acid (an unsaturated compound having a carboxyl group, such as acrylic acid, methacrylic acid, or maleic anhydride).

The heat seal layer 14 may be a polyolefin film.

The polyolefin film includes a polyolefin. The polyolefin may or may not have carboxyl group/carboxyl group salt. Examples of the polyolefin include low density polyethylene (LDPE), linear low density polyethylene (LLDPE), medium density polyethylene (MDPE), high density polyethylene (HDPE), ethylene-vinyl acetate copolymer, propylene homopolymer, ethylene-propylene block copolymer, and ethylene-propylene random copolymer. These can be used alone or in combination of two or more thereof.

In the heat seal layer 14, the content of the polyolefin may be, for example, 50 mass % or more, 70 mass % or more, 90 mass % or more, or 100 mass %.

The heat seal layer 14 may contain other components in addition to the polyolefin. Examples of other components include a silane coupling agent, an adhesion imparting agent such as an organometallic compound, various antifoaming agents, and a leveling agent. In addition, the heat seal layer 14 may contain an additive such as wax in order to impart slidability and blocking resistance.

The thickness of the heat seal layer 14 is in a range of 2 to 5 μm. When the thickness of the heat seal layer 14 is 2 μm or more, the seal strength of the first seal portion 30A and the second seal portion 30B can be further improved as compared with the case where the thickness of the heat seal layer 14 is less than 2 μm, and the durability of the packaging 100 can be improved. When the thickness of the heat seal layer 14 is 5 μm or less, the mass ratio of the paper substrates 11 and 21 in the total mass of the packaging 100 can be further increased as compared with the case where the thickness of the heat seal layer 14 exceeds 5 μm. When the heat seal layer 14 is a coating film obtained by coating and drying an aqueous dispersion in which a polyolefin having carboxyl group/carboxyl group salt is dispersed in water as a resin component, the polyolefin water dispersion is easily applied.

The thickness of the heat seal layer 14 may be 2.2 μm or more, 2.5 μm or more, or 3.0 μm or more. The thickness of the heat seal layer 14 may be 4.5 μm or less, or may be 4 μm or less.

The heat seal layer 14 may be made of a single layer or a multilayer of two or more layers.

### (Adhesive Layer)

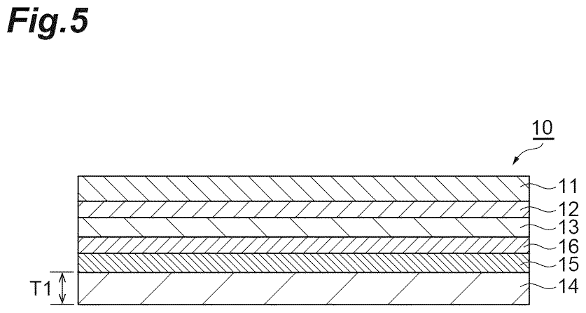

When the heat seal layer 14 is a polyolefin film, as illustrated in FIG. 5, the body member 10 may further include an adhesive layer 15 between the vapor deposition layer 13 and the heat seal layer 14. In this case, adhesion between the vapor deposition layer 13 and the heat seal layer 14 can be improved, and peeling between the vapor deposition layer 13 and the heat seal layer 14 can be suppressed.

The adhesive layer 15 contains an adhesive. The adhesive is not particularly limited, but examples of the adhesive include a two-liquid curable urethane adhesive.

The adhesive may have a gas barrier property.

The thickness of the adhesive layer 15 is not particularly limited, but is preferably 1 to 5 μm.

### (Overcoat Layer)

As illustrated in FIG. 5, the body member 10 may further include an overcoat layer 16 between the vapor deposition layer 13 and the adhesive layer 15. The overcoat layer 16 is not particularly limited, but the same material as the anchor coat layer 12 can be used. Such an overcoat layer 16 is excellent in flexibility, and can suppress cracking of the vapor deposition layer 13 together with the anchor coat layer 12 even when the body member 10 is bent, and can further improve the gas barrier property of the body member 10.

The material of the overcoat layer 16 may be the same as or different from the material of the anchor coat layer 12.

### <Bottom Member>

As described above, the bottom member 20 includes a paper substrate 21, an anchor coat layer 22, a vapor deposition layer 23, and a heat seal layer 24 in this order.

### (Paper Substrate)

As the paper substrate 21, a paper substrate similar to the paper substrate 11 can be used. The paper substrate 21 may be the same as or different from the paper substrate 11 in terms of material, thickness, basis weight, and the like.

The ratio P of the thickness of the paper substrate 21 of the bottom member 20 to the total thickness (T1+T2) of the heat seal layer 14 of the body member 10 and the heat seal layer 24 of the bottom member 20 is not particularly limited, and may be 0.5 or less, or may be greater than 0.5, but is preferably greater than 0.5.

In this case, the mass ratio of the paper substrates 11 and 21 in the total mass of the packaging 100 can be easily increased.

The ratio P may be 0.8 or more, 1.0 or more, 1.1 or more, or 1.2 or more. The ratio P may be 5.0 or less, 3.0 or less, 2.5 or less, 2.0 or less, or 1.5 or less.

### (Anchor Coat Layer)

As the anchor coat layer 22, an anchor coat layer similar to the anchor coat layer 12 can be used. The anchor coat layer 22 may be the same as or different from the anchor coat layer 12 in terms of material, thickness, and the like.

### (Vapor Deposition Layer)

As the vapor deposition layer 23, a vapor deposition layer similar to the vapor deposition layer 13 can be used. The vapor deposition layer 23 may be the same as or different from the vapor deposition layer 13 in terms of material, thickness, and the like.

### (Heat Seal Layer)

As the heat seal layer 24, a heat seal layer similar to the heat seal layer 14 can be used.

However, the ratio R of the thickness T2 of the heat seal layer 24 of the bottom member 20 to the thickness T1 of the heat seal layer 14 of the body member 10 is 5 or more. In this case, compared with the case where the ratio R is less than 5, when the packaging includes: a first seal portion 30A formed by heat-sealing peripheral portions of the body portions 10a of the pair of body members 10; and a second seal portion 30B formed by heat-sealing peripheral portions of the bottom portions 10b of the pair of body members 10 and a peripheral portion of the bottom member 20, the heat seal layer 24 of the bottom member 20 having a thickness sufficiently larger than that of the body member 10 is melted, and at the intersection X between the first seal portion 30A and the second seal portion 30B of the packaging 100, the melted heat seal layer 24 sufficiently fills the space to suppress the generation of a gap.

The ratio R may be 7 or more, 8 or more, 10 or more, 13 or more, or 15 or more. The ratio R may be 100 or less, 80 or less, 60 or less, 40 or less, 20 or less, 18 or less, 15 or less, or 10 or less.

The heat seal layer 24 may be a coating film obtained by coating and drying an aqueous dispersion in which a polyolefin having carboxyl group/carboxyl group salt is dispersed in water as a resin component, or may be a polyolefin film, but is preferably a polyolefin film. In this case, the heat seal layer 24 of the bottom member 20 is a polyolefin film. Therefore, the strength of the bottom member 20 is more improved compared to the case where the heat seal layer 24 is the above-described coating film, and even when the bottom member 20 is bent in the packaging 100 to have a bent portion 20a, the gas barrier property of the bent portion 20a can be further improved.

The polyolefin contained in the heat seal layer 24 may be the same as or different from the polyolefin contained in the heat seal layer 14 of the body member 10, but is preferably the same. For example, when the polyolefin contained in the heat seal layer 24 is polyethylene, the polyolefin contained in the heat seal layer 14 of the body member 10 is preferably polyethylene. In this case, in the second seal portion 30B, adhesion between the heat seal layer 14 of the body member 10 and the heat seal layer 24 of the bottom member 20 can be further improved.

### (Adhesive Layer)

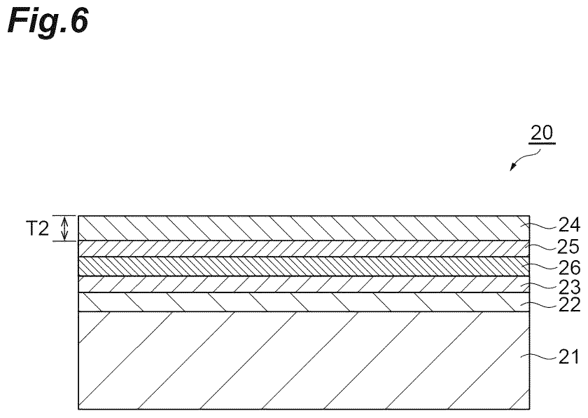

When the heat seal layer 24 is a polyolefin film, as illustrated in FIG. 6, the bottom member 20 may further include an adhesive layer 25 between the vapor deposition layer 23 and the heat seal layer 24. In this case, adhesion between the vapor deposition layer 23 and the heat seal layer 24 can be improved, and peeling between the vapor deposition layer 23 and the heat seal layer 24 can be suppressed.

The adhesive layer 25 contains an adhesive. The adhesive is not particularly limited, but examples of the adhesive include a two-liquid curable urethane adhesive.

The adhesive may have a gas barrier property.

The thickness of the adhesive layer 25 is not particularly limited, but is preferably 1 to 5 μm.

### (Overcoat Layer)

As illustrated in FIG. 6, the bottom member 20 may further include an overcoat layer 26 between the vapor deposition layer 23 and the adhesive layer 25. The overcoat layer 26 is not particularly limited, but the same material as the anchor coat layer 22 can be used. The overcoat layer 26 is excellent in flexibility, and can suppress cracking of the vapor deposition layer 23 together with the anchor coat layer 22 even when the bottom member 20 is bent, and can further improve the gas barrier property of the bottom member 20.

The material of the overcoat layer 26 may be the same as or different from the material of the anchor coat layer 22.

### <Mass Ratio of Paper Substrate in Total Mass of Packaging>

The mass ratio of the paper substrates 11 and 21 in the total mass of the packaging 100 is 70 mass % or more, but the mass ratio may be 75 mass % or more, and may be 80 mass % or more. The mass ratio may be 100 mass % or less, and may be 95 mass % or less.

### <Packaging Product>

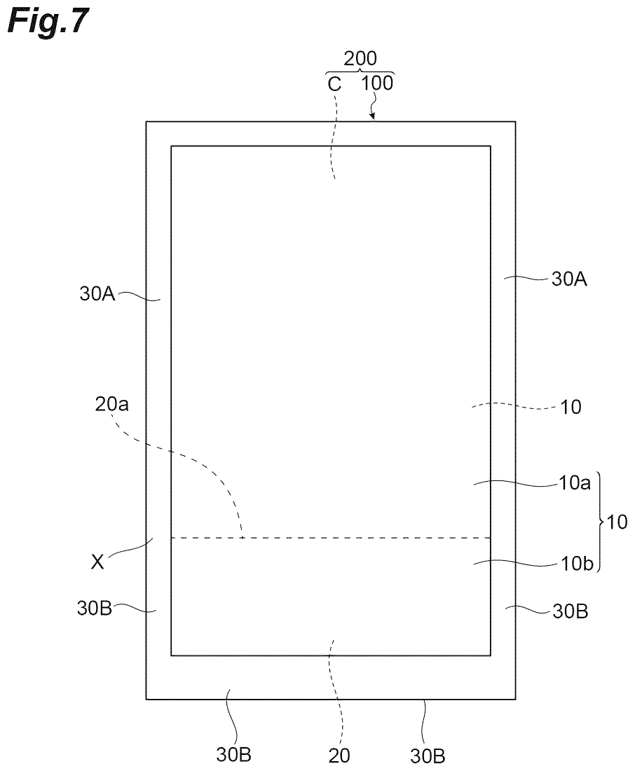

Next, an embodiment of the packaging product of the present disclosure will be described with reference to FIG. 7. FIG. 7 is a front view illustrating an embodiment of a packaging product of the present disclosure.

A packaging product 200 illustrated in FIG. 7 is obtained by sealing a content C in the packaging 100.

The packaging product 200 can improve gas barrier properties and durability while increasing the mass ratio of the paper substrates 11 and 21 in the total mass of the packaging 100, and can also improve the sealing property. After housing the content C, the packaging 100 is heat-sealed at the upper edge portions forming the opening portion of the pair of body members 10. Thereby, the content C can be hermetically sealed.

Examples of the content C include foods, pharmaceuticals, liquids, and electronic components.

Note that the outline of the present disclosure is as follows.
[1] A packaging having a standing pouch shape, the packaging including: a pair of body members having a body portion and a bottom portion, and a bottom member bent and inserted between the pair of body members; a first seal portion formed by heat-sealing peripheral portions of the body portions of the pair of body members; and a second seal portion formed by heat-sealing peripheral portions of the bottom portions of the pair of body members and a peripheral portion of the bottom member, wherein the body member and the bottom member include a paper substrate, an anchor coat layer, a vapor deposition layer containing a metal or a metal oxide, and a heat seal layer in this order, the first seal portion is formed by heat-sealing the heat seal layers of the pair of body members, the second seal portion is formed by heat-sealing the heat seal layer of the body member and the heat seal layer of the bottom member, a thickness of the heat seal layer of the body member is in a range of 2 to 5 μm, a ratio of a thickness of the heat seal layer of the bottom member to a thickness of the heat seal layer of the body member is 5 or more, and a mass ratio of the paper substrate to a total mass of the packaging is 70 mass % or more.
[2] The packaging according to [1], wherein no gap is formed at an intersection between the first seal portion and the second seal portion.
[3] The packaging according to [1] or [2], wherein the heat seal layer of the body member is formed of a coating film obtained by coating and drying an aqueous dispersion in which a polyolefin having at least one selected from the group consisting of a carboxyl group and a salt of a carboxyl group is dispersed in water as a resin component, and the heat seal layer of the bottom member is a polyolefin film.
[4] The packaging according to [3], wherein the bottom member further includes an adhesive layer between the vapor deposition layer and the heat seal layer.
[5] The packaging according to [4], wherein the bottom member further includes an overcoat layer between the vapor deposition layer and the adhesive layer.
[6] The packaging according to [5], wherein the overcoat layer has a polyolefin having at least one selected from the group consisting of a carboxyl group and a salt of a carboxyl group.
[7] The packaging according to any of [1] to [6], wherein a ratio of a thickness of the paper substrate of the bottom member to a total thickness of the heat seal layer of the body member and the heat seal layer of the bottom member is greater than 0.5.
[8] The packaging according to any of [1] to [7], wherein a ratio of a thickness of the paper substrate of the bottom member to a total thickness of the heat seal layer of the body member and the heat seal layer of the bottom member is 5.0 or less.
[9] The packaging according to any of [1] to [8], wherein, in the body member and the bottom member, the anchor coat layer has a polyolefin having at least one selected from the group consisting of a carboxyl group and a salt of a carboxyl group.
[10] The packaging according to any of [1] to [8], wherein, in the body member and the bottom member, the anchor coat layer contains a polyvinyl alcohol.
[11] The packaging according to any of [1] to [8], wherein, in the body member and the bottom member, the anchor coat layer contains a polyurethane-based resin.
[12] The packaging according to any of [1] to [11], wherein a ratio of a thickness of the heat seal layer of the bottom member to a thickness of the heat seal layer of the body member is 100 or less.
[13] The packaging according to any of [1] to [12], wherein the paper substrate is an uncoated paper having no clay coat layer.
[14] A packaging product obtained by sealing a content in the packaging according to any of [1] to [13].

### EXAMPLES

Hereinafter, the present disclosure will be described in more detail with reference to examples, but the present disclosure is not limited to these examples.

### Example 1

### <Production of Body Member>

As the paper substrate, prepared was a clay-coated paper in which a clay coat layer having a thickness of 5 μm was formed on one side of the paper having a thickness of 55 μm (basis weight: 60 g/m²). On the clay coat layer of the clay-coated paper, a coating liquid for forming an anchor coat layer was applied and dried so that the thickness was 3 μm after drying, thereby forming the anchor coat layer. At this time, as the coating liquid for forming an anchor coat layer, used was an aqueous dispersion in which a polyolefin having carboxyl group/carboxyl group salt is dispersed in water as a resin component (manufactured by Mitsui Chemicals, Inc., trade name: “CHEMIPEARL S500”, hereinafter, also referred to as “polyolefin coat 1”).

Thereafter, an Al layer having a thickness of 50 nm was formed on the anchor coat layer by a vacuum vapor deposition method.

Next, onto the surface of the Al layer, a coating liquid for forming a heat seal layer was applied and dried so that the thickness was 3 μm after drying, thereby forming the heat seal layer. At this time, as the coating liquid for forming a heat seal layer, the polyolefin coat 1, which was the same as the coating liquid for forming an anchor coat layer, was used.

In this way, a body member having a dimension of 200 mm in length×150 mm in width was produced.

### <Production of Bottom Member>

As the paper substrate, prepared was a clay-coated paper in which a clay coat layer having a thickness of 5 μm was formed on one side of the paper having a thickness of 55 μm (basis weight: 60 g/m²). On the clay coat layer of the clay-coated paper, a coating liquid for forming an anchor coat layer was applied and dried so that the thickness was 3 μm after drying, thereby forming the anchor coat layer. At this time, as the coating liquid for forming an anchor coat layer, the polyolefin coat 1, which was the same as the coating liquid for forming an anchor coat layer in the body member, was used.

Thereafter, an Al layer having a thickness of 50 nm was formed on the anchor coat layer by a vacuum vapor deposition method.

Next, onto the Al layer, a coating liquid for forming an overcoat layer was applied and dried so that the thickness was 3 μm after drying, thereby forming the overcoat layer. At this time, as the coating liquid for forming an overcoat layer, used was an aqueous dispersion in which a polyolefin having carboxyl group/carboxyl group salt is dispersed in water as a resin component (polyolefin coat 1).

Next, onto the surface of the overcoat layer, a urethane curable adhesive as an adhesive was applied so that the application amount after drying was 2 μm, and an LLDPE film having a thickness of 40 μm was bonded thereto. At this time, as the urethane curable adhesive, used was a mixed solution obtained by mixing a polyester polyol (manufactured by Mitsui Chemicals, Inc., trade name: TAKELAC A525) as a main agent and a polyisocyanate (manufactured by Mitsui Chemicals, Inc., trade name: TAKENATE A52) as a curing agent and diluting the mixture with ethyl acetate.

In this way, a bottom member having a dimension of 150 mm in length×70 mm in width was produced.

### <Preparation of Packaging Having Standing Pouch Shape>

Using a pair of body members and one bottom member obtained as described above, a packaging having a standing pouch shape was prepared with a normal bag making machine for a packaging having a standing pouch shape.

Specifically, the pair of body members was made to face each other, with the heat seal layers directed inward; the bottom member was folded so that the heat seal layer was directed outward, and inserted between the body members; the peripheral portion of the bottom member and the peripheral portion of the bottom portion of the body member were heat-sealed to form the second seal portion (bottom seal portion); and both of the edge portions of the pair of body members were heat-sealed to form the first seal portion (side seal portion).

The upper end portions of the pair of body members were not heat-sealed.

In this way, produced was a packaging having a standing pouch shape, having a dimension of 200 mm in length×150 mm in width×35 mm in folding in front view, and having an opening at the top. The “folding” refers to a folding depth from the lower end of the body member to the bent portion of the bottom member.

When the obtained packaging was observed at the intersection between the first seal portion and the second seal portion, no gap was formed.

### Example 2

A packaging was prepared in the same manner as in Example 1 except that the overcoat layer was not formed when the bottom member was prepared.

When the obtained packaging was observed at the intersection between the first seal portion and the second seal portion, no gap was formed.

### Example 3

A packaging was prepared in the same manner as in Example 1 except that a PVA coating liquid (solid content: 5 mass %) in which a polyvinyl alcohol (PVA) having a polymerization degree of 500 (manufactured by Kuraray Co., Ltd., trade name: “Poval 5-98”) is dissolved in a mixed solvent of water and isopropyl alcohol (IPA) (water/IPA=90/10 (mass ratio)) was prepared, and the PVA coating liquid was applied so that the thickness after drying was 3 μm to form the anchor coat layer when the bottom member and the body member were produced.

When the obtained packaging was observed at the intersection between the first seal portion and the second seal portion, no gap was formed.

### Example 4

A packaging was prepared in the same manner as in Example 1, except that a clay-coated paper in which a clay coat layer having a thickness of 4 μm was formed on the paper having a thickness of 46 μm (basis weight: 50 g/m²) was used as the paper substrate when the bottom member and the body member were produced, and an LLDPE film having a thickness of 30 μm was used as the heat seal layer when the bottom member was produced.

When the obtained packaging was observed at the intersection between the first seal portion and the second seal portion, no gap was formed.

### Example 5

A packaging was prepared in the same manner as in Example 1, except that a clay-coated paper in which a clay coat layer having a thickness of 4 μm was formed on the paper having a thickness of 46 μm (basis weight: 50 g/m²) was used as the paper substrate when the bottom member and the body member were produced, and an LLDPE film having a thickness of 20 μm was used as the heat seal layer when the bottom member was produced.

When the obtained packaging was observed at the intersection between the first seal portion and the second seal portion, no gap was formed.

### Example 6

A packaging was produced in the same manner as in Example 1 except that the thickness of the heat seal layer was 2.5 μm in producing the body member.

When the obtained packaging was observed at the intersection between the first seal portion and the second seal portion, no gap was formed.

### Example 7

A packaging was produced in the same manner as in Example 1 except that the thickness of the heat seal layer was 4.8 μm in producing the body member.

When the obtained packaging was observed at the intersection between the first seal portion and the second seal portion, no gap was formed.

### Example 8

A packaging was prepared in the same manner as in Example 1 except that an aqueous dispersion of a polyurethane-based resin (PU) (manufactured by Mitsui Chemicals, Inc., trade name: “TAKELAC WPB-341”, solid content concentration: 30 mass %) was used, and the PU coating liquid was applied so that the thickness after drying was 3 μm to form the anchor coat layer when the bottom member and the body member were produced.

When the obtained packaging was observed at the intersection between the first seal portion and the second seal portion, no gap was formed.

### Example 9

A packaging was prepared in the same manner as in Example 1 except that an aqueous dispersion in which a polyolefin having carboxyl group/carboxyl group salt is dispersed in water as a resin component (manufactured by Sumitomo Seika Chemicals Company, Limited., trade name: “ZAIKTHENE AC”, hereinafter, also referred to as “polyolefin coat 2”) was applied so that the thickness after drying was 3 μm to form the anchor coat layer when the bottom member and the body member were produced.

When the obtained packaging was observed at the intersection between the first seal portion and the second seal portion, no gap was formed.

### Example 10

A packaging was produced in the same manner as in Example 3, except that kraft paper (basis weight: 50 g/m²) having a thickness of 50 μm was used as the paper substrate when the bottom member and the body member were produced.

When the obtained packaging was observed at the intersection between the first seal portion and the second seal portion, no gap was formed.

### Comparative Example 1

A packaging was prepared in the same manner as in Example 1 except that only a heat seal layer with a thickness of 3 μm was formed on the Al vapor deposition layer, instead of forming the overcoat layer, the adhesive layer, and the heat seal layer thereon when the bottom member was produced, and the heat seal layer was formed by using the coating liquid for forming a heat seal layer that was used when the body member was produced (polyolefin coat 1).

When the obtained packaging was observed at the intersection between the first seal portion and the second seal portion, a gap was formed.

### Comparative Example 2

A packaging was produced in the same manner as in Example 1, except that an LLDPE film having a thickness of 10 μm was used as the heat seal layer when the bottom member was produced.

When the obtained packaging was observed at the intersection between the first seal portion and the second seal portion, a gap was formed.

### Reference Example 1

A packaging was produced in the same manner as in Example 1 except that the bottom member of Example 2 was used as the body member.

When the obtained packaging was observed at the intersection between the first seal portion and the second seal portion, no gap was formed.

### <Calculation of Mass Ratio of Paper Substrate>

The mass ratio A of the paper substrate to the total mass of the packaging was calculated based on the following equation. The results are shown in Tables 1 to 4.

A(mass %)=100×[Mass of paper substrate(clay-coated paper) in bottom member B1(g)+Mass of paper substrate(clay-coated paper) in body member B2×2(g)]/[Mass of bottom member C1(g)+Mass of body member C2×2(g)]

B1, B2, C1, and C2 were calculated using the following parameters.
Area of bottom member S1=150 mm×70 mm
Area of body member S2=200 mm×150 mm
Density of anchor coat layer (polyolefin coat 1): 1.0 g/cm³
Density of anchor coat layer (polyolefin coat 2): 1.0 g/cm³
Density of anchor coat layer (PVA film): 1.2 g/cm³
Density of vapor deposition layer: 2.7 (g/cm³)
Density of overcoat layer (polyolefin coat 1): 1.0 g/cm³
Density of adhesive layer: 1.5 (g/cm³)
Density of heat seal layer (LLDPE): 0.9 g/cm³
Density of heat seal layer (polyolefin coat 1): 1.0 g/cm³

### <Evaluation of Durability>

For each packaging obtained in Examples 1 to 10, Comparative Examples 1 to 2, and Reference Example 1, 30 g of plastic resin was added as a content from the opening, and then the upper ends of the body members of the packaging were heat-sealed with each other to hermetically seal the content. Thus, three test samples were prepared.

Then, a dropping bag test was performed as follows: each test sample was dropped from the position where the height from the floor surface was 100 cm, and the number of times of dropping the bag was counted until the bag busted. Then, the average value of the number of times of dropping the bag for the three test samples was calculated as the number of times of dropping the bag, and the number of times of dropping the bag was used as an index of durability. The results are shown in Tables 1 to 4.

Incidentally, the number of times of dropping the bag was up to 20. When the bag was not dropped after 20 times, subsequent dropping bag tests were not performed, and the number of times of dropping the bag was regarded as 20 times.

### <Evaluation of Gas Barrier Property>

For each packaging obtained in Examples 1 to 10, Comparative Examples 1 to 2, and Reference Example 1, 30 g of calcium chloride was added, air was removed as much as possible, and then the upper ends of the pair of body members were heat-sealed with each other to enclose the calcium chloride, thereby obtaining a first test sample.

The first test sample was stored in an environment of 40 °C and 90%, the state of the calcium chloride was checked after storage for 1 month, and whether the calcium chloride showed deliquescence was examined. Whether the calcium chloride showed deliquescence was used as an index of gas barrier properties. The results are shown in Tables 1 to 4. When there is deliquescence, infiltration of moisture into the first test sample is not suppressed, and the gas barrier property of the first test sample is not good.

### <Evaluation of Sealing Property of Packaging Product>

For each packaging obtained in Examples 1 to 10, Comparative Examples 1 to 2, and Reference Example 1, 20 ml of a penetrant liquid (Color check, manufactured by TASETO Co., Ltd.) was poured from the opening, and distributed throughout the packaging to obtain a second test sample as a packaging product. After 5 minutes passed, the second test sample was observed from the outside, and whether the penetrant liquid exuded was examined. Whether the penetrant liquid exuded was used as an index of sealing property.

TABLE 1

| | | | Example 1 | Example 2 | Example 3 | Example 4 |
|---|---|---|---|---|---|---|
| Body | Paper sSubstrate | | Clay-coated paper | Clay-coated paper | Clay-coated paper | Clay-coated paper |
| member | | | 60 g/m² | 60 g/m² | 60 g/m² | 50 g/m² |
| | | | (paper substrate 55 | (paper substrate 55 | (paper substrate 55 | (paper substrate 46 |
| | | | μm/ | μm/ | μm/ | μm/ |
| | | | clay coat 5 μm) | clay coat 5 μm) | clay coat 5 μm) | clay coat 4 μm) |
| | Anchor coat layer | | Polyolefin coat 1 | Polyolefin coat 1 | PVA | Polyolefin coat 1 |
| | | | (carboxyl | (carboxyl | [3 μm] | (carboxyl |
| | | | group/carboxyl | group/carboxyl | | group/carboxyl |
| | | | group salt) | group salt) | | group salt) |
| | | | [3 μm] | [3 μm] | | [3 μm] |
| | Vapor deposition | | Al | Al | Al | Al |
| | layer | | [50 nm] | [50 nm] | [50 nm] | [50 nm] |
| | Adhesive layer | | — | — | — | — |
| | Heat seal layer | | Polyolefin coat 1 | Polyolefin coat 1 | Polyolefin coat 1 | Polyolefin coat 1 |
| | [Thickness T1] | | (carboxyl | (carboxyl | (carboxyl | (carboxyl |
| | | | group/carboxyl | group/carboxyl | group/carboxyl | group/carboxyl |
| | | | group salt) | group salt) | group salt) | group salt) |
| | | | [3 μm] | [3 μm] | [3 μm] | [3 μm] |
| Bottom | Paper substrate | | Clay-coated paper | Clay-coated paper | Clay-coated paper | Clay-coated paper |
| member | | | 60 g/m² | 60 g/m² | 60 g/m² | 50 g/m² |
| | | | (paper substrate 55 | (paper substrate 55 | paper substrate 55 | (paper substrate 46 |
| | | | μm/ | μm/ | μm/ | μm/ |
| | | | clay coat 5 μm) | clay coat 5 μm) | clay coat 5 μm) | clay coat 4 μm) |
| | Anchor coat layer | | Polyolefin coat 1 | Polyolefin coat 1 | PVA | Polyolefin coat 1 |
| | | | (carboxyl | (carboxyl | [3 μm] | (carboxyl |
| | | | group/carboxyl | group/carboxyl | | group/carboxyl |
| | | | group salt) | group salt) | | group salt) |
| | | | [3 μm] | [3 μm] | | [3 μm] |
| | Vapor deposition | | Al | Al | Al | Al |
| | layer | | [50 mm] | [50 nm] | [50 nm] | [50 nm] |
| | Overcoat layer | | Polyolefin coat 1 | — | Polyolefin coat 1 | Polyolefin coat 1 |
| | | | (carboxyl | | (carboxyl | (carboxyl |
| | | | group/carboxyl | | group/carboxyl | group/carboxyl |
| | | | group salt) | | group salt) | group salt) |
| | | | [3 μm] | | [3 μm] | [3 μm] |
| | Adhesive layer | | Urethane curable | Urethane curable | Urethane curable | Urethane curable |
| | | | adhesive | adhesive | adhesive | adhesive |
| | | | [2 μm] | [2 μm] | [2 μm] | [2 μm] |
| | Heat seal layer | | LLDPE | LLDPE | LLDPE | LLDPE |
| | [Thickness T2] | | [40 μm] | [40 μm] | [40 μm] | [30 μm] |
| Mass ratio of paper substrate to | | | 84% | 84% | 83% | 82% |
| total mass of standing pouch | | | | | | |
| T2/T1 | | | 13 | 13 | 13 | 10 |
| Ratio of thickness of paper | | | 1.28 | 1.28 | 1.28 | 1.39 |
| substrate of bottom member to | | | | | | |
| T1 + T2 | | | | | | |
| Evalu- | Scaling property of | | No permeation | No permeation | No permeation | No permeation |
| ation | packaging product | | | | | |
| | Gas barrier property | | No deliquescence | No deliquescence | No deliquescence | No deliquescence |
| | Dura- | The number | 20 | 20 | 20 | 19 |
| | bility | of times of | | | | |
| | | dropping the | | | | |
| | | bag (time) | | | | |

TABLE 2

| | | | Example 5 | Example 6 | Example 7 |
|---|---|---|---|---|---|
| Body | Paper substrate | | Clay-coated paper | Clay-coated paper | Clay-coated paper |
| member | | | 50 g/m² | 60 g/m² | 60 g/m² |
| | | | (paper substrate | (paper substrate | (paper substrate |
| | | | 46 μm/ | 55 μm/ | 55 μm/ |
| | | | clay coat 5 μm) | clay coat 5 μm) | clay coat 5 μm) |
| | Anchor coat layer | | Polyolefin coat 1 | Polyolefin coat 1 | Polyolefin coat 1 |
| | | | (carboxyl | (carboxyl | (carboxyl |
| | | | group/carboxyl group | group/carboxyl group | group/carboxyl group |
| | | | salt) | salt) | salt) |
| | | | [3 μm] | [3 μm] | [3 μm] |
| | Vapor deposition layer | | Al | Al | Al |
| | | | [50 nm] | [50 nm] | [50 nm] |
| | Adhesive layer | | — | — | — |
| | Heat seal layer | | Polyolefin coat 1 | Polyolefin coat 1 | Polyolefin coat 1 |
| | [Thickness T1] | | (carboxyl | (carboxyl | carboxyl |
| | | | group/carboxyl group | group/carboxyl group | group/carboxyl group |
| | | | salt) | salt) | salt) |
| | | | [3 μm] | [2.5 μm] | [4.8 μm] |
| Bottom | Paper substrate | | Clay-coated paper | Clay-coated paper | Clay-coated paper |
| member | | | 50 g/m² | 60 g/m² | 60 g/m² |
| | | | (paper substrate | (paper substrate | (paper substrate |
| | | | 46 μm/ | 55 μm/ | 55 μm/ |
| | | | clay coat 5 μm) | clay coat 5 μm) | clay coat 5 μm) |
| | Anchor coat layer | | Polyolefin coat 1 | Polyolefin coat 1 | Polyolefin coat 1 |
| | | | (carboxyl | (carboxyl | (carboxyl |
| | | | group/carboxyl group | group/carboxyl group | group/carboxyl group |
| | | | salt) | salt) | salt) |
| | | | [3 μm] | [3 μm] | [3 μm] |
| | Vapor deposition layer | | Al | Al | Al |
| | | | [50 nm] | [50 nm] | [50 nm] |
| | Overcoat layer | | Polyolefin coat 1 | Polyolefin coat 1 | Polyolefin coat 1 |
| | | | (carboxyl | (carboxyl | (carboxyl |
| | | | group/carboxyl group | group/carboxyl group | group/carboxyl group |
| | | | salt) | salt) | salt) |
| | | | [3 μm] | [3 μm] | [3 μm] |
| | Adhesive layer | | Urethane curable | Urethane curable | Urethane curable |
| | | | adhesive | adhesive | adhesive |
| | | | [2 μm] | [2 μm] | [2 μm] |
| | Heat seal layer | | LLDPE | LLDPE | LLDPE |
| | [Thickness T2] | | [20 μm] | [40 μm] | [40 μm] |
| Mass ratio of paper substrate to total | | | 84% | 84% | 81% |
| mass of standing pouch | | | | | |
| T2/T1 | | | 7 | 16 | 8 |
| Ratio of thickness of paper substrate | | | 2.00 | 1.29 | 1.23 |
| of bottom member to T1 + T2 | | | | | |
| Evaluation | Scaling property of | | No permeation | No permeation | No permeation |
| | packaging product | | | | |
| | Gas barrier property | | No deliquescence | No deliquescence | No deliquescence |
| | Durability | The number of | 17 | 18 | 20 |
| | | times of | | | |
| | | dropping the bag | | | |
| | | (time) | | | |

TABLE 3

| | | | Example 8 | Example 9 | Example 10 |
|---|---|---|---|---|---|
| Body | Paper substrate | | Clay-coated paper | Clay-coated paper | Kraft paper |
| member | | | 60 g/m² | 60 g/m² | 50 g/m² |
| | | | (paper substrate | (paper substrate | (50 μm) |
| | | | 55 μm/ | 55 μm/ | |
| | | | clay coat 5 μm) | clay coat 5 μm) | |
| | Anchor coat layer | | PU | Polyolefin coat 2 | PVA |
| | | | [3 μm] | (carboxy] | [3 μm] |
| | | | | group/carboxyl group | |
| | | | | salt) | |
| | | | | [3 μm] | |
| | Vapor deposition layer | | Al | Al | Al |
| | | | [50 nm] | [50 nm] | [50 nm] |
| | Adhesive layer | | — | — | — |
| | Heat seal layer | | Polyolefin coat 1 | Polyolefin coat 1 | Polyolefin coat 1 |
| | [Thickness T1] | | (carboxyl | (carboxyl | (carboxyl |
| | | | group/carboxyl group | group/carboxyl group | group/carboxyl group |
| | | | salt) | salt) | salt) |
| | | | [3 μm] | [3 μm] | [3 μm] |
| Bottom | Paper substrate | | Clay-coated paper | Clay-coated paper | Kraft paper |
| member | | | 60 g/m² | 60 g/m² | 50 g/m² |
| | | | (paper substrate | (paper substrate | (50 μm) |
| | | | 55 μm/ | 55 μm/ | |
| | | | clay coat 5 μm) | clay coat 5 μm) | |
| | Anchor coat layer | | PU | Polyolefin coat 2 | PVA |
| | | | [3 μm] | (carboxyl | [3 μm] |
| | | | | group/carboxyl group | |
| | | | | salt) | |
| | | | | [3 μm] | |
| | Vapor deposition layer | | Al | Al | Al |
| | | | [50 nm] | [50 nm] | [50 nm] |
| | Overcoat layer | | Polyolefin coat 1 | Polyolefin coat 1 | Polyolefin coat 1 |
| | | | (carboxyl | (carboxyl | (carboxyl |
| | | | group/carboxyl group | group/carboxyl group | group/carboxyl group |
| | | | salt) | salt) | salt) |
| | | | [3 μm] | [3 μm] | [3 μm] |
| | Adhesive layer | | Urethane curable | Urethane curable | Urethane curable |
| | | | adhesive | adhesive | adhesive |
| | | | [2 μm] | [2 μm] | [2 μm] |
| | Heat seal layer | | LLDPE | LLDPE | LLDPE |
| | [Thickness T2] | | [40 μm] | [40 μm] | [40 μm] |
| Mass ratio of paper substrate to total | | | 82% | 83% | 80% |
| mass of standing pouch | | | | | |
| T2/T1 | | | 13 | 13 | 13 |
| Ratio of thickness of paper substrate of | | | 1.28 | 1.28 | 1.16 |
| bottom member to T1 + T2 | | | | | |
| Evaluation | Sealing property of | | No permeation | No permeation | No permeation |
| | packaging product | | | | |
| | Gas barrier property | | No deliquescence | No deliquescence | No deliquescence |
| | Durability | The number of | 15 | 16 | 20 |
| | | times of | | | |
| | | dropping the bag | | | |
| | | (time) | | | |

TABLE 4

| | | | Comparative | Comparative | Reference |
|---|---|---|---|---|---|
| | | | Example 1 | Example 2 | Example 1 |
| Body | Paper substrate | | Clay-coated paper | Clay-coated paper | Clay-coated paper |
| member | | | 60 g/m² | 60 g/m² | 60 g/m² |
| | | | (paper substrate | (paper substrate | (paper substrate |
| | | | 55 μm/ | 55 μm/ | 55 μm/ |
| | | | clay coat 5 μm) | clay coat 5 μm) | clay coat 5 μm ) |
| | Anchor coat layer | | Polyolefin coat 1 | Polyolefin coat 1 | Polyolefin coat 1 |
| | | | (carboxyl | (carboxyl | (carboxyl |
| | | | group/carboxyl group | group/carboxyl group | group/carboxyl group |
| | | | salt) | salt) | salt) |
| | | | [3 μm] | [3 μm] | [3 μm] |
| | Vapor deposition layer | | Al | Al | Al |
| | | | [50 nm] | [50 nm] | [50 nm] |
| | Adhesive layer | | — | — | Urethane curable |
| | | | | | adhesive |
| | | | | | [2 μm] |
| | Heat seal layer | | Polyolefin coat 1 | Polyolefin coat 1 | LLDPE |
| | [Thickness T1] | | (carboxyl | (carboxyl | [40 μm] |
| | | | group/carboxyl group | group/carboxyl group | |
| | | | salt) | salt) | |
| | | | [3 μm] | [3 μm] | |
| Bottom | Paper substrate | | Clay-coated paper | Clay-coated paper | Clay-coated paper |
| member | | | 60 g/m² | 60 g/m² | 60 g/m² |
| | | | (paper substrate | (paper substrate | (paper substrate |
| | | | 55 μm/ | 55 μm/ | 55 μm/ |
| | | | clay coat 5 μm) | clay coat 5 μm) | clay coat 5 μm ) |
| | Anchor coat layer | | Polyolefin coat 1 | Polyolefin coat 1 | Polyolefin coat 1 |
| | | | (carboxyl | (carboxyl | (carboxyl |
| | | | group/carboxyl group | group/carboxyl group | group/carboxyl group |
| | | | salt) | salt) | salt) |
| | | | [3 μm] | [3 μm] | [3 μm] |
| | Vapor deposition layer | | Al | Al | Al |
| | | | [50 nm] | [50 nm] | [50 nm] |
| | Overcoat layer | | — | Polyolefin coat 1 | — |
| | | | | (carboxyl | |
| | | | | group/carboxyl group | |
| | | | | salt) | |
| | | | | [3 μm] | |
| | Adhesive layer | | — | Urethane curable | Urethane curable |
| | | | | adhesive | adhesive |
| | | | | [2 μm] | [2 μm] |
| | Heat seal layer | | Polyolefin coat 1 | LLDPE | LLDPE |
| | [Thickness T2] | | (carboxyl | [10 μm] | [40 μm] |
| | | | group/carboxyl group | | |
| | | | salt) | | |
| | | | [3 μm] | | |
| Mass ratio of paper substrate to total | | | 91% | 87% | 57% |
| mass of standing pouch | | | | | |
| T2/T1 | | | 1 | 3 | 1 |
| Ratio of thickness of paper substrate | | | 9.17 | 4.23 | 0.69 |
| of bottom member to T1 + T2 | | | | | |
| Evaluation | Sealing property of | | Permeation | Permeation | No permeation |
| | packaging product | | | | |
| | Gas barrier property | | Deliquescent | Slightly deliquescent | No deliquescence |
| | Durability | The number of | 9 | 10 | 20 |
| | | times of | | | |
| | | dropping the bag | | | |
| | | (time) | | | |

From the results shown in Tables 1 to 4, it was found that the packaging of Examples 1 to 10 enables an increased mass ratio of the paper substrate. All the first test samples obtained by sealing calcium chloride in the packaging of Examples 1 to 10 were rated as “No deliquescence”. On the other hand, the first test samples obtained by sealing calcium chloride in the packaging of Comparative Examples 1 to 2 were rated as “Deliquescent” or “Slightly deliquescent”. Therefore, it was found that the packaging of Examples 1 to 10 had a higher gas barrier property than that of Comparative Examples 1 to 2. Further, all of the second test samples obtained by pouring the penetrant liquid in the packaging of Examples 1 to 10 were rated as “No permeation”. On the other hand, the second test samples obtained by sealing calcium chloride in the packaging of Comparative Examples 1 to 2 were rated as “Permeation”. Therefore, it was found that the packaging of Examples 1 to 10 can improve the sealing property of the second test sample as compared with Comparative Examples 1 to 2.

From the above, it was confirmed that the packaging of the present disclosure can improve gas barrier properties and durability while increasing the mass ratio of a paper substrate, and can also improve the sealing property of a packaging product obtained by sealing a content.

### REFERENCE SIGNS LIST

10 Body member
10a Body portion
10b Bottom portion
11, 21 Paper substrate
12, 22 Anchor coat layer
13, 23 Vapor deposition layer
14, 24 Heat seal layer
15, 25 Adhesive layer
16, 26 Overcoat layer
20 Bottom member
30A First seal portion
30B Second seal portion
100 Packaging
200 Packaging product
X Intersection
T1 Thickness of heat seal layer of body member
T2 Thickness of heat seal layer of bottom member
C Content

1. A packaging having a standing pouch shape, the packaging comprising: a pair of body members having a body portion and a bottom portion, and a bottom member bent and inserted between the pair of body members; a first seal portion formed by heat-sealing peripheral portions of the body portions of the pair of body members; and a second seal portion formed by heat-sealing peripheral portions of the bottom portions of the pair of body members and a peripheral portion of the bottom member, wherein
the body member and the bottom member include a paper substrate, an anchor coat layer, a vapor deposition layer containing a metal or a metal oxide, and a heat seal layer in this order,
the first seal portion is formed by heat-sealing the heat seal layers of the pair of body members,
the second seal portion is formed by heat-sealing the heat seal layer of the body member and the heat seal layer of the bottom member,
a thickness of the heat seal layer of the body member is in a range of 2 to 5 μm,
a ratio of a thickness of the heat seal layer of the bottom member to a thickness of the heat seal layer of the body member is 5 or more, and
a mass ratio of the paper substrate to a total mass of the packaging is 70 mass % or more.

2. The packaging according to claim 1, wherein no gap is formed at an intersection between the first seal portion and the second seal portion.

3. The packaging according to claim 1, wherein the heat seal layer of the body member is formed of a coating film obtained by coating and drying an aqueous dispersion in which a polyolefin having at least one selected from the group consisting of a carboxyl group and a salt of a carboxyl group is dispersed in water as a resin component, and
the heat seal layer of the bottom member is a polyolefin film.

4. The packaging according to claim 3, wherein the bottom member further includes an adhesive layer between the vapor deposition layer and the heat seal layer.

5. The packaging according to claim 4, wherein the bottom member further includes an overcoat layer between the vapor deposition layer and the adhesive layer.

6. The packaging according to claim 5, wherein the overcoat layer has a polyolefin having at least one selected from the group consisting of a carboxyl group and a salt of a carboxyl group.

7. The packaging according to claim 1, wherein a ratio of a thickness of the paper substrate of the bottom member to a total thickness of the heat seal layer of the body member and the heat seal layer of the bottom member is greater than 0.5.

8. The packaging according to claim 7, wherein a ratio of a thickness of the paper substrate of the bottom member to a total thickness of the heat seal layer of the body member and the heat seal layer of the bottom member is 5.0 or less.

9. The packaging according to claim 1, wherein, in the body member and the bottom member, the anchor coat layer has a polyolefin having at least one selected from the group consisting of a carboxyl group and a salt of a carboxyl group.

10. The packaging according to claim 1, wherein, in the body member and the bottom member, the anchor coat layer contains a polyvinyl alcohol.

11. The packaging according to claim 1, wherein, in the body member and the bottom member, the anchor coat layer contains a polyurethane-based resin.

12. The packaging according to claim 1, wherein a ratio of a thickness of the heat seal layer of the bottom member to a thickness of the heat seal layer of the body member is 100 or less.

13. The packaging according to claim 1, wherein the paper substrate is an uncoated paper having no coating layer.

14. A packaging product obtained by sealing a content in the packaging according to claim 1.
